(19) United States
(12) Patent Application Publication
(10) Pub. No.: US 2025/0267866 A1
(43) Pub. Date: Aug. 21, 2025

(54) MEMORY DEVICE

(71) Applicant: MACRONIX International Co., Ltd., Hsinchu (TW)

(72) Inventor: Li-Yen Liang, Kaohsiung City (TW)

(73) Assignee: MACRONIX International Co., Ltd., Hsinchu (TW)

(21) Appl. No.: 18/582,676

(22) Filed: Feb. 21, 2024

(51) Int. Cl. H10B 43/27

(52) U.S. Cl. CPC H10B 43/27

(57) ABSTRACT

A memory device includes a substrate, an interconnect, first and second stop pads located above the interconnect, a stacked structure located above the first and second stop pads, a channel pillar extending through the stacked structure, a charge storage structure located between the channel pillar and the stacked structure, first and second conductive pillars located in and coupled to the channel pillar, and a first conductive plug located between the interconnect and the first stop pad. The first conductive pillar lands on the first stop pad. The second conductive pillar lands on the second stop pad. The first conductive pillar is electrically connected to a first device on the substrate through the first conductive plug, the first stop pad, and the interconnect. The memory device may include a 3D AND flash memory with high capacity and high performance.

### BACKGROUND

### Technical Field

The embodiments of the present disclosure relate to a semiconductor device and particularly to a memory device.

### Description of Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which may be applied to a multi-dimensional memory array with high integration and high area utilization, and has an advantage of a fast operation speed. Therefore, the development of a 3D memory device has gradually become the current trend. However, there are still many challenges associated with the 3D memory device.

### SUMMARY

The embodiments of the present disclosure provide a memory device and a method of fabricating the same in which a width of bit lines is increased, a distance between the bit lines is increased to reduce resistance, and the complexity of the manufacturing process is lowered, and the memory device and the method of fabricating the same may be integrated with existing manufacturing processes.

In an embodiment of the present disclosure, a memory device includes a substrate, an interconnect, a first stop pad and a second stop pad, a stacked structure, a channel pillar, a charge storage structure, a first conductive pillar and a second conductive pillar, and a first conductive plug. The interconnect is located above the substrate. The first stop pad and the second stop pad are located above the interconnect. The stacked structure is located above the first stop pad and the second stop pad. The channel pillar extends through the stacked structure. The charge storage structure is located between the channel pillar and the stacked structure. The first conductive pillar and the second conductive pillar are located in the channel pillar and coupled to the channel pillar, where the first conductive pillar lands on the first stop pad, and the second conductive pillar lands on the second stop pad. The first conductive plug is located between the interconnect and the first stop pad, where the first conductive pillar is electrically connected to a first device on the substrate through the first conductive plug, the first stop pad, and the interconnect.

In an embodiment of the present disclosure, a memory device includes a substrate, an interconnect, a plurality of first stop pads and a plurality of second stop pads, a stacked structure, a channel pillar, a charge storage structure, a plurality of pairs of conductive pillars, and a plurality of first conductive plugs. The first stop pads and the second stop pads are located above the interconnect. The stacked structure is located above the first stop pads and the second stop pads. The channel pillars extend through the stacked structure and are arranged in two adjacent rows. Each of the pairs of the conductive pillars is disposed in one of the channel pillars, a first conductive pillar of the each of the pairs of the conductive pillars lands on one of the first stop pads, and a second conductive pillar of the each of the pairs of the conductive pillars lands on one of the second stop pads. The first conductive plugs are located between the interconnect and the first stop pads, where each of the first conductive pillars is electrically connected to a first device on the substrate through a corresponding first conductive plug of the first conductive plugs, a corresponding first stop pad of the first stop pads, and the interconnect. The second conductive pillars are adjacent to each other and are located between the first conductive pillars.

In view of the above, in the memory device provided in one or more embodiments of the present disclosure, the source lines of the memory device are formed below the stacked structure, while the bit lines are formed above the stacked structure. Therefore, the density of the conductive lines (the bit lines) above the stacked structure is reduced, and the width of and the distance between the conductive lines (the bit line) are increased. As a result, the resistance value is reduced, and the difficulty of the manufacturing process is lowered. In addition, the source lines are electrically connected to source pillars through the stop pads located below the source pillars and the conductive plugs that penetrate the stop pads. Therefore, the memory device provided in one or more embodiments of the present disclosure may be integrated with the existing manufacturing processes.

### BRIEF DESCRIPTION OF THE DRAWINGS

FIG. 1A is a circuit diagram of a 3D AND flash memory array according to some embodiments.

FIG. 1B is a partial perspective view of a part of the memory array in FIG. 1A.

FIG. 1C and FIG. 1D are cross-sectional views taken along the line I-I′ in FIG. 1B.

FIG. 1E is a top view of the line II-II′ in FIG. 1B, FIG. 1C, and FIG. 1D.

FIG. 2A is a cross-sectional view of a memory device according to an embodiment of the present disclosure.

FIG. 2B is a current path diagram of the equivalent circuit of one memory cell in FIG. 2A in during operation.

FIG. 2C is a current path diagram of the equivalent circuit of another memory cell in FIG. 2A during operation.

FIG. 3 is an enlarged view of the partial region in FIG. 2A.

FIG. 4A is a top view of one memory device in FIG. 2A.

FIG. 4B is a top view of another memory element in FIG. 2A.

FIG. 5A to FIG. 5H are cross-sectional views of a method for manufacturing a memory device according to an embodiment of the present disclosure.

### DESCRIPTION OF THE EMBODIMENTS

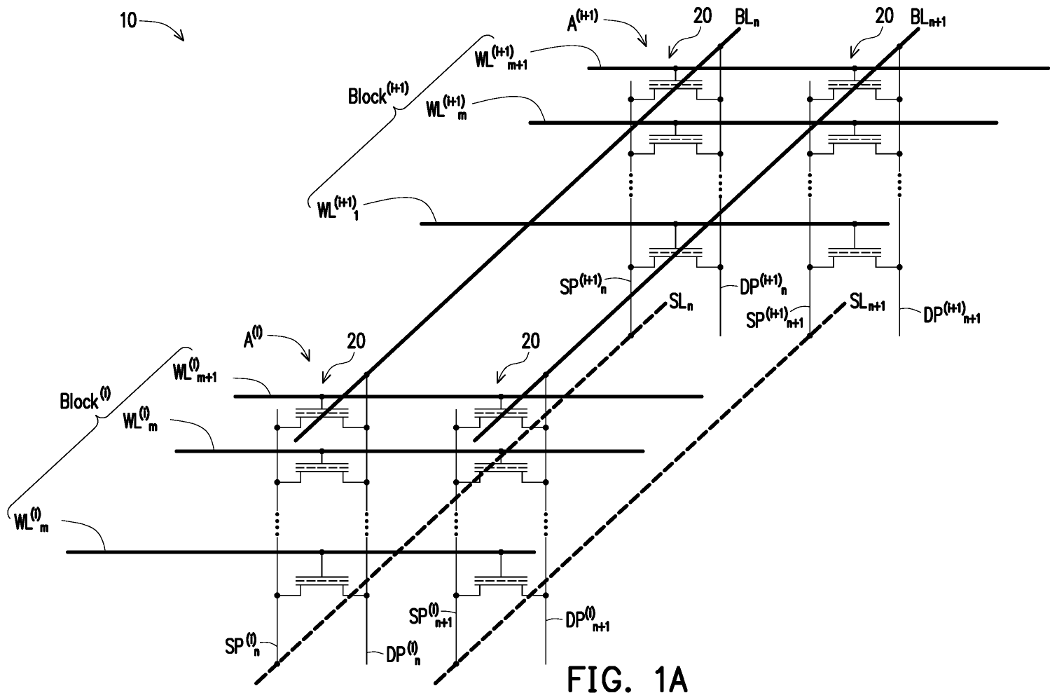

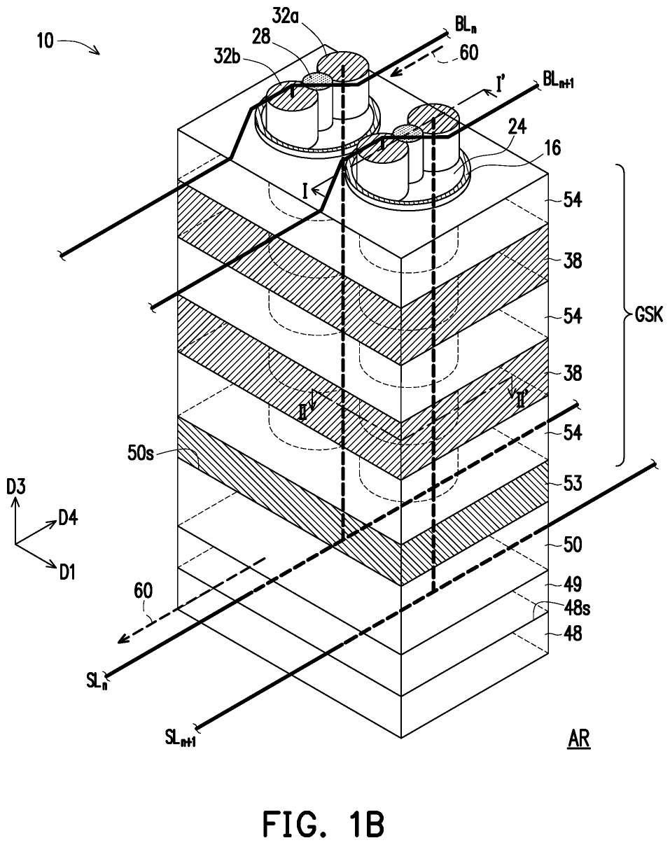

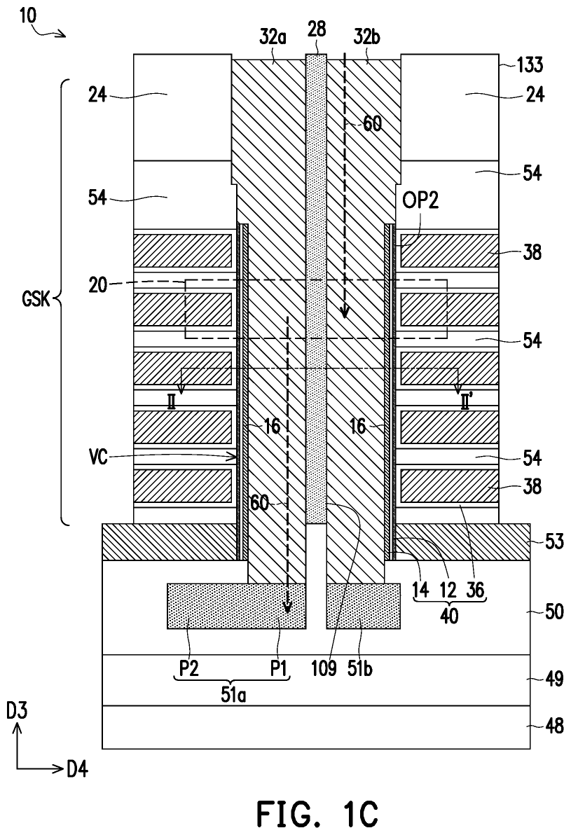

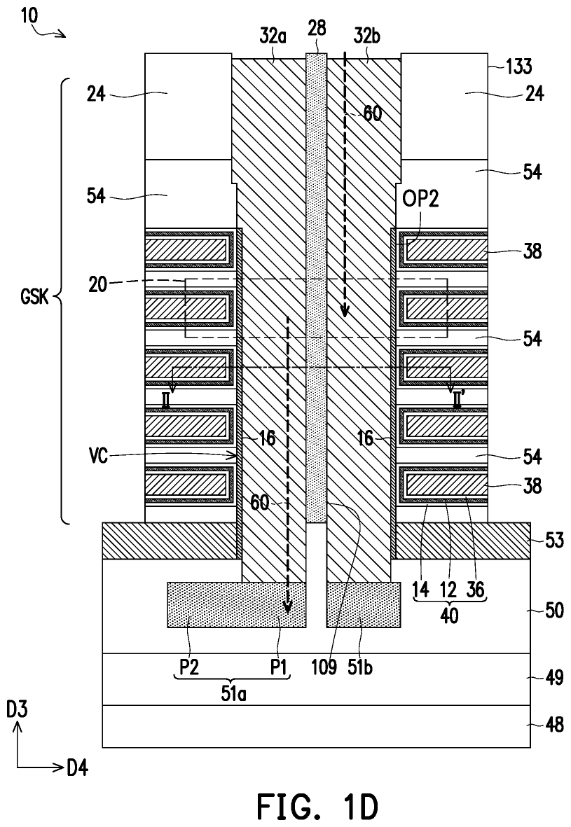

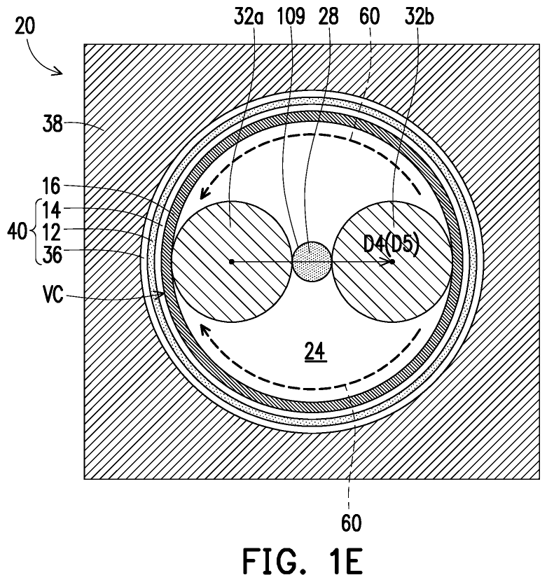

FIG. 1A is a circuit diagram of a 3D AND flash memory array according to some embodiments. FIG. 1B is a partial perspective view of a part of the memory array in FIG. 1A. FIG. 1C and FIG. 1D are cross-sectional views taken along the line I-I′ in FIG. 1B. FIG. 1E is a top view of the line II-II′ in FIG. 1B, FIG. 1C, and FIG. 1D.

FIG. 1A is a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an nth column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may be located on a dielectric layer 50 over an interconnect structure 49 of a semiconductor die. The interconnect structure is located over one or more active devices (e.g., transistors) formed on a semiconductor substrate. The memory array 10 may include a stacked structure GSK, multiple channel pillars 16, multiple first conductive pillars (also referred to as source pillars) 32a, multiple second conductive pillars (also referred to as drain pillars) 32b, and multiple charge storage structures 40.

Referring to FIG. 1B, the stacked structure GSK is formed on the dielectric layer 50. The stacked structure GSK located at a memory array region AR of the substrate 48 includes multiple gate layers (also referred to as word lines or conductive layers) 38 and multiple insulating layer 54 vertically stacked on a surface 50s of the dielectric layer 50. In a direction Z, the gate layers 38 are electrically isolated from each other by the insulating layer 54 located therebetween. A material of the gate layers 38 may include tungsten. A material of the insulating layers 54 may include silicon oxide. The gate layers 38 extend in a direction parallel to a surface 48s of the substrate 48. The gate layers 38 in a staircase region (not shown) of the substrate 48 may have a staircase structure. Therefore, a lower gate layer 38 is longer than an upper gate layer 38, and the end of the lower gate layer 38 extends laterally beyond the end of the upper gate layer 38. Contacts (not shown) for connecting the gate layers 38 may land on the ends of the gate layers 38 to connect the gate layers 38 respectively to conductive lines.

Referring to FIG. 1B to FIG. 1D, the memory array 10 further includes multiple channel pillars 16. The channel pillars 16 extend continuously through the stacked structure GSK located at the memory array region to the conductive layer 53 between the dielectric layer 50 and the stacked structure GSK. In some embodiments, each channel pillar 16 may have a ring shape from a top view. The material of the channel pillars 16 may include semiconductor, such as undoped polysilicon. The material of the conductive layer 53 may include doped polysilicon. In some embodiments, the material of the conductive layer 53 may include P-type doped polysilicon.

Referring to FIG. 1B to FIG. 1D, the memory array 10 further includes multiple insulating pillars 28, multiple first conductive pillars 32a, and multiple second conductive pillars 32b. In this example, the first conductive pillars 32a serve as source pillars. The second conductive pillars 32b serve as drain pillars. The first conductive pillars 32a, the second conductive pillars 32b, and the insulating pillars 28 each extend in a direction D3 perpendicular to a surface of the gate layer 38. The first conductive pillar 32a and the second conductive pillar 32b are separated by the insulating pillar 28 and surrounded by an insulating filling layer 24. The first conductive pillar 32a and the second conductive pillar 32b are electrically connected to the channel pillar 16. The first conductive pillar 32a and the second conductive pillar 32b may include doped polysilicon or metal materials. The insulating pillar 28 may include silicon nitride or silicon oxide, and the insulating filling layer 24 may include silicon oxide.

Referring to FIG. 1C and FIG. 1D, a charge storage structure 40 is located between the channel pillar 16 and the gate layers (or called conductive layers) 38. The charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (e.g., the tunneling layer 14 and the charge storage layer 12) of the charge storage structure 40 continuously extends in a direction (i.e., the direction Z) perpendicular to the gate layer 38, and another portion (e.g., the blocking layer 36) of the charge storage structure 40 surrounds the gate layer 38. In other embodiments, as shown in FIG. 1D, the charge storage structure 40 (e.g., the tunneling layer 14, the charge storage layer 12, and the blocking layer 36) surrounds the gate layer 38.

Referring to FIG. 1E, the charge storage structure 40, the channel pillar 16, the source pillar 32a, and the drain pillar 32b are surrounded by the gate layer 38, and a memory cell 20 is accordingly defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vₜₕ) of the corresponding memory cell 20 is applied, a channel region of the channel pillar 16 intersecting the selected word line 38 is turned on to allow a current to enter the drain pillar 32b from the bit line BLₙ or BLₙ₊₁ (shown in FIG. 1B), flow to the source pillar 32a via the turned-on channel region (e.g., in a direction indicated by arrow 60), and finally flow to the source line SLₙ or SLₙ₊₁ (shown in FIG. 1B).

Referring to FIG. 1B, the source lines SLₙ and SLₙ₊₁ and the bit lines BLₙ and BLₙ₊₁ are positioned on different sides of the stacked structure GSK in an embodiment of the present disclosure to avoid having the source lines SLₙ and SLₙ₊₁ and the bit lines BLₙ and BLₙ₊₁ in the same layer, preventing excessive density and reducing the complexity of the manufacturing process. Additionally, the source lines SLₙ and SLₙ₊₁ and the bit lines BLₙ and BLₙ₊₁ may even be separately configured with larger widths.

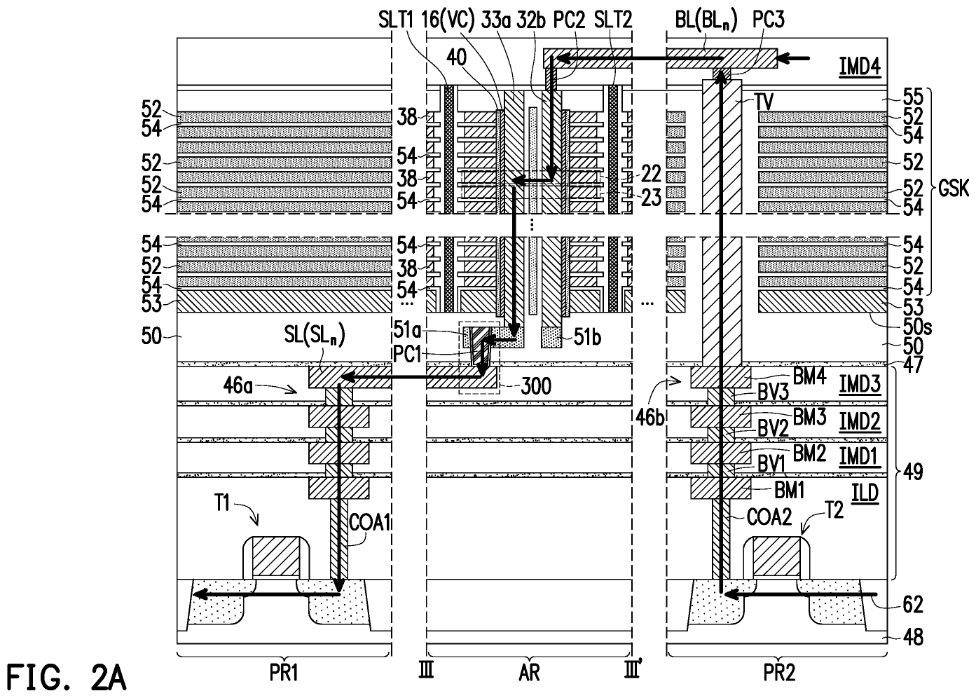

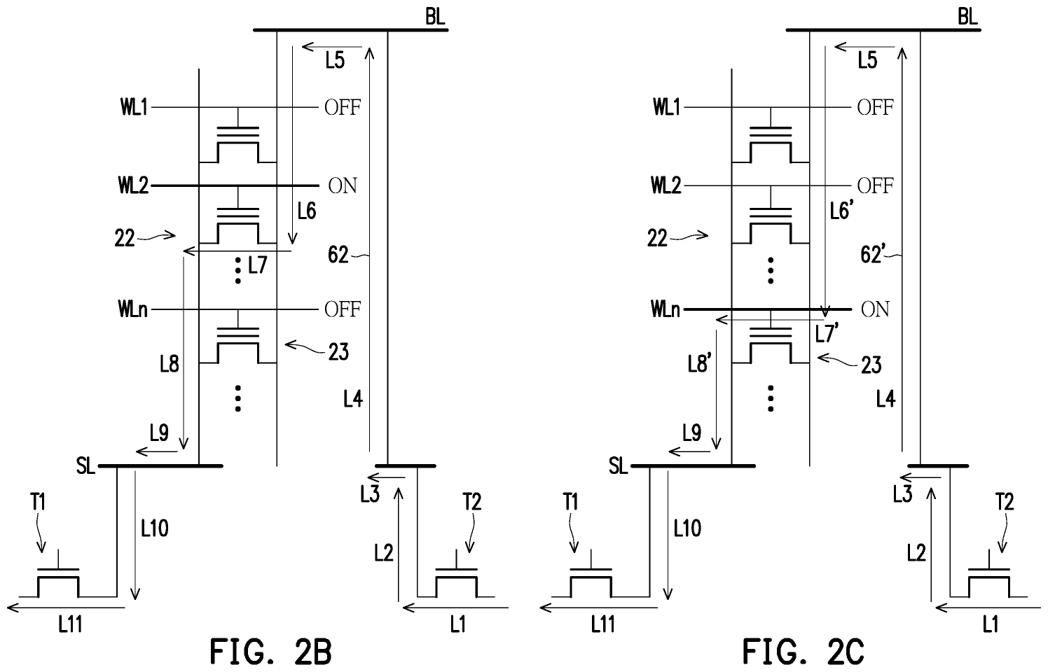

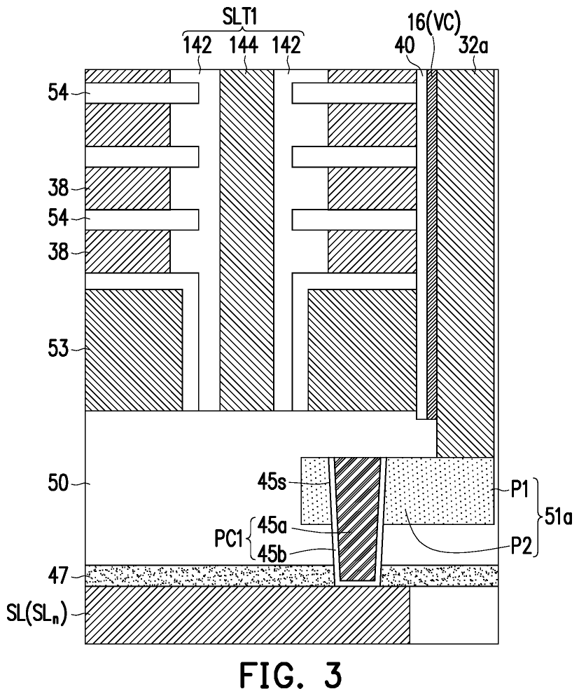

FIG. 2A is a cross-sectional view of a memory device according to an embodiment of the present disclosure. FIG. 2B is a current path diagram of the equivalent circuit of one memory cell in FIG. 2A in during operation. FIG. 2C is a current path diagram of the equivalent circuit of another memory cell in FIG. 2A during operation. FIG. 3 is an enlarged view of the partial region 300 in FIG. 2A.

Referring to FIG. 2A, in an embodiment of the present disclosure, the source line SL (e.g., the source line SLₙ) connecting the source pillar 32a is disposed below the stacked structure GSK, and the bit line BL (e.g., the bit line BLₙ) connecting the drain pillar 32b is disposed above the stacked structure GSK. The source line SL (e.g., the source line SLₙ) and the bit line BL (e.g., the bit line BLₙ) may be formed through conductive lines and therefore may be referred to as the conductive lines. By distributing multiple conductive lines serving as multiple source lines SL (e.g., the source line SLₙ) to be located below the stacked structure GSK, the density of the conductive lines on top of the stacked structure GSK is reduced, and the distance between the conductive lines serving as the bit lines BL (e.g., the bit line BLₙ) is increased, thereby reducing the difficulty of the manufacturing process. Detailed explanations are provided below with reference of the drawings.

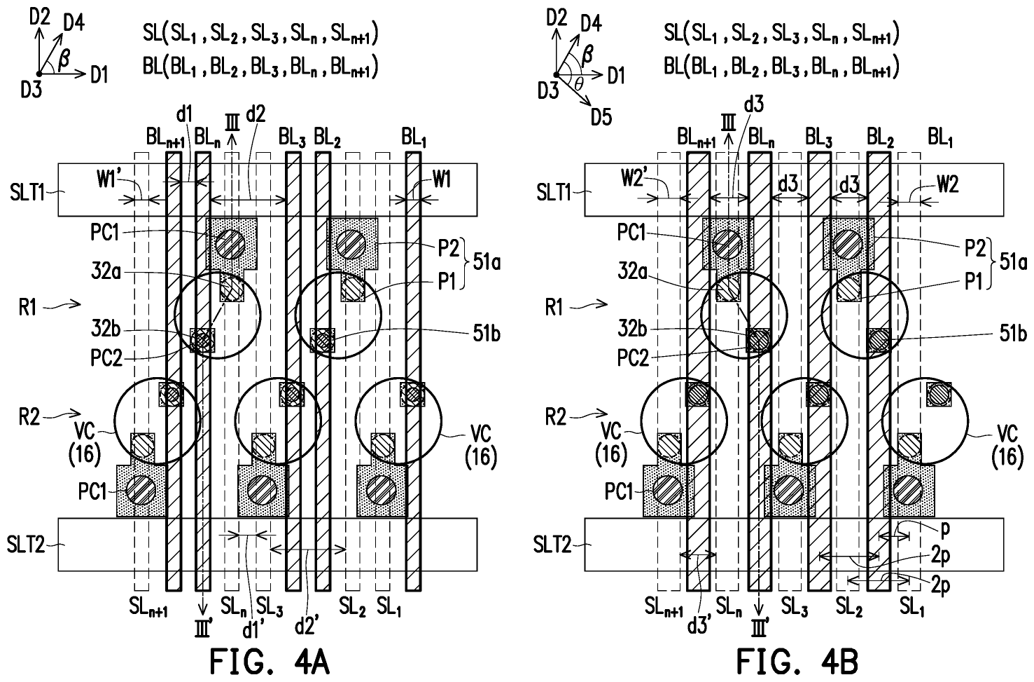

FIG. 4A is a top view of one memory device in FIG. 2A. FIG. 4B is a top view of another memory element in FIG. 2A. A schematic cross-sectional view taken along the line III-III′ in FIG. 4A and FIG. 4B is as shown by the memory array region AR in FIG. 2A.

Referring to FIG. 2A, FIG. 3, FIG. 4A, and FIG. 4B, in the embodiment of the present disclosure, the source pillar 32a lands on the stop pad 51a and is connected to the source line SL (e.g., the source line SLₙ) disposed below the stacked structure GSK through a conductive plug PC1. The source line SL (e.g., the source line SLₙ) is electrically coupled to a device T1 on the substrate 48 through an interconnect 46a.

Referring to FIG. 2A, FIG. 4A, and FIG. 4B, the stop pads 51a and 51b are adjacent to each other and are disposed in the dielectric layer 50. An area occupied by the stop pad 51a is larger than an area occupied by the stop pad 51b. Referring to FIG. 3, FIG. 4A, and FIG. 4B, the stop pad 51a includes a first portion P1 and a second portion P2. The first portion P1 of the stop pad 51a is within a range of a channel pillar 16 of a channel pillar structure VC and is overlapped with a range surrounded by the channel pillar structure VC. A top surface of the first portion P1 of the stop pad 51a is connected to a bottom surface of the source pillar 32a. The second portion P2 of the stop pad 51a is located outside the channel pillar structure VC and is not overlapped with the range surrounded by the channel pillar structure VC. The second portion P2 of the stop pad 51a is connected to the conductive plug PC1.

Referring to FIG. 3, the conductive plug PC1 extends from a top surface of the second portion P2 of the stop pad 51a to a bottom surface of the second portion P2, penetrates the dielectric layer 50 and a stop layer 47, and is coupled to the source line SL (e.g., the source line SLₙ). In this embodiment, a sidewall 45s of the conductive plug PC1 is connected to the second portion P2 of the stop pad 51a, and the bottom surface of the conductive plug PC1 is connected to the top surface of the source line SL (e.g., the source line SLₙ). The conductive plug PC1 may include a metal layer 45a and a barrier layer (or known as an adhesive layer) 45b. The barrier layer 45b surrounds a sidewall and a bottom surface of the metal layer 45a. The metal layer 45a includes tungsten. The barrier layer 45b includes titanium, tantalum, titanium nitride, tantalum nitride, or a combination thereof. In an embodiment of the present disclosure, the source line SL (e.g., the source line SLₙ) is disposed below the stacked structure GSK and is connected to the drain pillar 32b through the conductive plug PC1 and the stop pad 51a. Therefore, referring to FIG. 2A, the top surface of the source pillar 32a is completely covered by the dielectric layer 55, and no conductive plug lands on an upper surface of the source pillar 32a.

Referring to FIG. 2A, the source line SL is connected to the interconnect 46a of the interconnect structure 49. The interconnect 46a is a part of the interconnect structure 49. The interconnect structure 49 includes multiple dielectric layers ILD, IMD1, IMD2, and IMD3 and multiple metal layers (or known as the conductive lines) BM1, BM2, BM3, and BM4 and multiple vias BV1, BV2, and BV3 located in the dielectric layers ILD, IMD1, IMD2, IMD3. Materials of the metal layers BM1, BM2, BM3, and BM4, a contact plug COA1, and the vias BV1, BV2, and BV3 include a metal layer and a barrier layer. The metal layer is, for instance, tungsten. The barrier layer surrounds the periphery and the bottom of the metal layer. A material of the barrier layers may include titanium (Ti), titanium nitride (TiN), tantalum (Ta), tantalum nitride (TaN), or a combination thereof. The interconnect 46a is composed of parts of the metal layers BM1, BM2, BM3, and BM4 and the vias BV1, BV2, and BV3. The interconnect 46a is electrically connected to the device T1 located in a peripheral region PR1. The device T1 is, for instance, a metal-oxide-semiconductor transistor.

Referring to FIG. 2A, the drain pillar 32b lands on the stop pad 51b and is connected to the bit line BL (BLₙ) located above the stacked structure GSK through the overlying conductive plug PC2. The bit line BL (BLₙ) is further electrically coupled to a device T2 on the substrate 48 through the conductive plug PC3, the through via TV, and an interconnect 46b.

Referring to FIG. 2A, FIG. 4A, and FIG. 4B, the stop pad 51b is located in the dielectric layer 50 and is connected to the drain pillar 32b. The stop pad 51b is located in the channel pillar 16 of the channel pillar structure VC, and the stop pad 51b mostly overlaps a range surrounded by the channel pillar structure VC. The conductive plug PC2 is located above the drain pillar 32b and is connected to the drain pillar 32b. The bit line BL (BLₙ) is located above the conductive plugs PC2 and PC3 and contacts top surfaces of the conductive plugs PC2 and PC3. The top surface of the conductive plug PC3 contacts the bit line BL (BLₙ).

The through via TV extends through the stacked structure GSK in the peripheral region PR2. The stacked structure GSK in the peripheral region PR2 includes multiple intermediate layers 52 and multiple insulating layers 54 alternately stacked on a surface 50s of the dielectric layer 50. A material of the intermediate layer 52 includes a dielectric material, such as silicon nitride. The material of the insulating layers 54 may include silicon oxide. The through via TV further penetrates the dielectric layer 50 and the stop layer 47 and is connected to the interconnect 46b. The stop layer 47 is located between the interconnect structure 49 and the dielectric layer 50. A material of the stop layer 47 is, for instance, silicon nitride.

The interconnect 46b is composed of another portion of the metal layers BM1, BM2, BM3, and BM4, a contact plug COA2, and the vias BV1, BV2, and BV3. The interconnect 46b is electrically connected to the device T2 located in the peripheral region PR2. The device T2 is, for instance, a metal-oxide-semiconductor transistor.

Referring to FIG. 2A, a direction indicated by an arrow is a current path 62 through which the current flows during operation. For instance, when a memory cell 22 is being operated (e.g., read), a voltage is applied to turn on the corresponding devices T2 and T1, and the voltage is applied to the selected word line (gate layer) WL2; for example, when a voltage higher than the corresponding threshold voltage (Vₜₕ) of the memory cell 22 is applied, a channel region of the channel pillar 16 intersecting the selected word line WL2 is turned on to allow a current to enter the drain pillar 32b from the bit line BL (BLₙ), flow to the source pillar 32a via the turned-on channel region in the channel pillar 16, flow to the source line SLₙ, and finally flow to the device T1 (e.g., in the direction indicated by current path 62).

Referring to FIG. 2B, the total length of the current path 62 of the memory cell 22 during operation is the sum of the lengths L1, L2, L3, L4, L5, L6, L7, L8, L9, and L10. The equivalent circuit of the operation memory cell 23 and the schematic diagram of the current path are shown in FIG. 2C. The total length of the current path 62′ of the memory cell 23 is the sum of the lengths L1, L2, L3, L4, L5, L6′, L7′, L8′, L9, and L10. Since the length L7 is equal to L7′, and the sum of the lengths L6 and L8 is equal to the sum of the lengths L6′ and L8′, therefore, when operating the same string of memory cells (for example, memory cells 22 and 23), regardless whether the memory cells are closer the lower devices T1 and T2 or the upper bit line BL, the lengths of the current paths are approximately the same.

Referring to FIG. 2A, FIG. 4A, and FIG. 4B, separation walls SLT1 and SLT2 extend through the stacked structure GSK. Multiple channel pillar structures VC are disposed in the stacked structure GSK between the separation walls SLT1 and SLT2, as shown in FIG. 4A and FIG. 4B. The channel pillar structures VC between the separation walls SLT1 and SLT2 may be arranged in two rows R1 and R2. In some embodiments, the stop pads 51a and 51b connecting the source pillar 32a and the drain pillar 32b may be disposed between the separation walls SLT1 and SLT2. In some other embodiments, the second portion P2 of the stop pad 51a may partially extend below the separation wall SLT1 and/or the separation wall SLT2 (not shown) and partially overlap the separation wall SLT1 and/or the separation wall SLT2 in the top view. The conductive plugs PC1 may be arranged in two rows, and in the top view, the channel pillars 16 arranged in the two adjacent rows R1 and R2 are located between the two rows of the conductive plugs PC1. The second portion P2 of the stop pad 51a in the row R1 and the conductive plug PC1 are located between the separation wall SLT1 and the source pillar 32a. The second portion P2 of the stop pad 51a in the row R2 and the conductive plug PCI are located between the separation wall SLT2 and the source pillar 32a.

Referring to FIG. 4A and FIG. 4B, the drain pillars 32b in the rows R1 and R2 are adjacent to each other. The source pillars 32a in the rows R1 and R2 are separated by the drain pillars 32b in the rows R1 and R2. In other words, the drain pillars 32b in the rows R1 and R2 are sandwiched between the source pillars 32a in the rows R1 and R2.

In some embodiments of the present disclosure, the source pillars 32a and the drain pillars 32b in the row R1 and the source pillars 32a and the drain pillars 32b in the row R2 may be arranged in the same direction D4, as shown in FIG. 4A. An angle ß between the direction D4 and the direction D1 in which the separation walls SLT1 and SLT2 extend is less than 90 degrees. In other embodiments of the present disclosure, the source pillars 32a and the drain pillars 32b in the row R1 and the source pillars 32a and the drain pillars 32b in the row R2 may be arranged in different directions D5 and D4. An angle θ between the directions D5 and D4 is, for instance, 90 degrees or ranges from 110 degrees to 120 degrees, as shown in FIG. 4B.

Referring to FIG. 4A and FIG. 4B, the source lines SL (e.g., SL₁, SL₂, SL₃, SLₙ, SLₙ₊₁) and the bit lines BL (e.g., BL₁, BL₂, BL₃, BLₙ, BLₙ₊₁) are respectively disposed below and above the separation walls SLT1 and SLT2, i.e., at the bottom portion and on the top portion of the figures. In this embodiment, the separation walls SLT1 and SLT2 above the source lines SL cross over the source lines SL. The bit lines BL cross over the underlying separation walls SLT1 and SLT2. The source lines SL are separated by a dielectric layer IMD3 (shown in FIG. 2A). The bit lines BL are separated by a dielectric layer IMD4 (shown in FIG. 2A). In the present disclosure, the source lines SL and the bit lines BL are not arranged at the same level, and not arranged at the same metal layer, therefore the density of the source lines SL and the density of the bit lines BL can be reduced respectively. The widths of the source lines SL and the distances between the source lines SL are increased, and the widths of the bit lines BL and the distances between of the bit lines BL are increased, whereby the difficulty of the manufacturing process is reduced.

A distance between the source lines SL and a distance between the bit lines BL are related to an arrangement direction of the source pillars 32a and the drain pillars 32b in the rows R1 and R2. Referring to FIG. 4A, when the arrangement direction of the source pillars 32a and the arrangement direction of the drain pillars 32b in the rows R1 and R2 are the same (e.g., both in the direction D4), there are at least two unequal distances d1′ and d2′ between the source lines SL. There are at least two unequal distances d1 and d2 between the bit lines BL. Each source line SL has a width W1′. Each bit line BL has a width W1.

Referring to FIG. 4B, when the arrangement direction of the source pillars 32a and the arrangement direction of the drain pillars 32b in the rows R1 and R2 are different (e.g., the directions D4 and D5), distances d3′ between the source lines SL are approximately equal or similar. Distances d3 between the bit lines BL are approximately equal or similar. Each source line SL has a width W2′. Each bit line BL has a width W2. Compared with the situation where the source lines SL and the bit lines BL are arranged at the same height (assuming that the original spacing is p), the pitch between the source lines SL and the bit lines BL in the embodiment of the present invention may be increased to two times (i.e. pitch 2p), thus reducing the difficulty of the process.

In an embodiment of the present disclosure, the distance d3 is greater than the distance d1, and the distance d3′ is greater than the distance d1′, and therefore the difficulty of the manufacturing process is further reduced. In addition, the width W2 is greater than the width W1, and the width W2′ is greater than the width W1′, and therefore the resistance values of the bit lines BL and the source lines SL are further reduced.

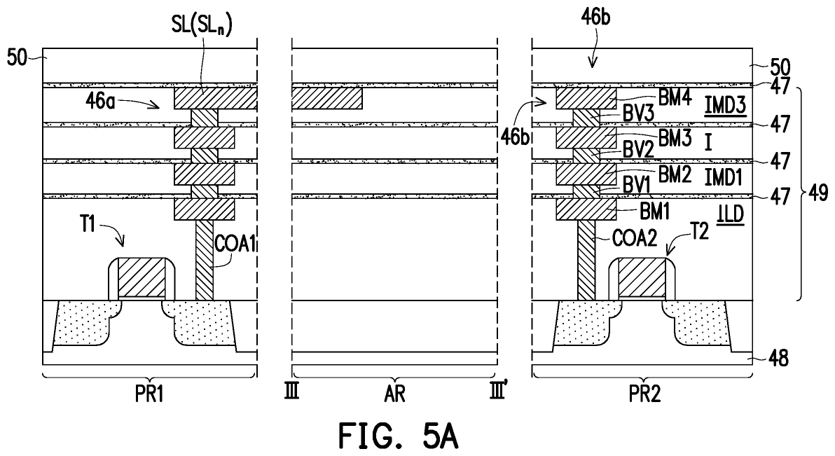

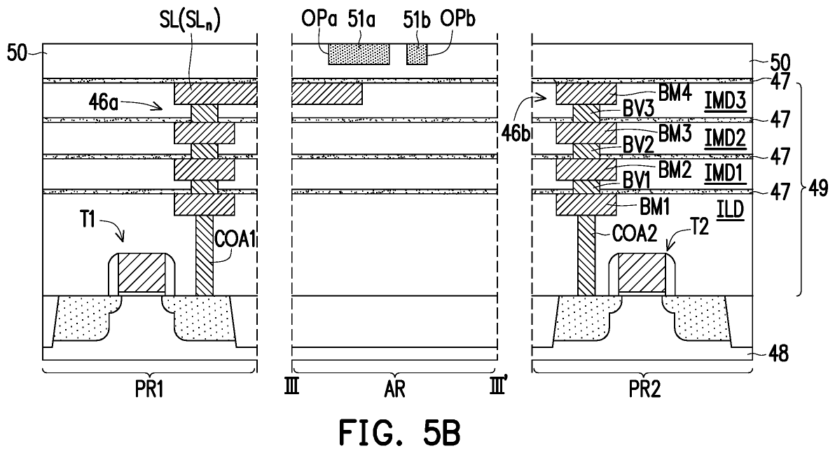

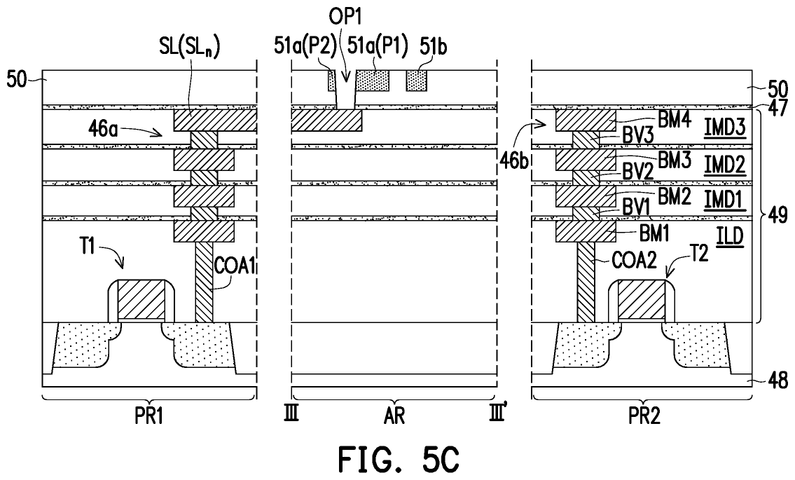

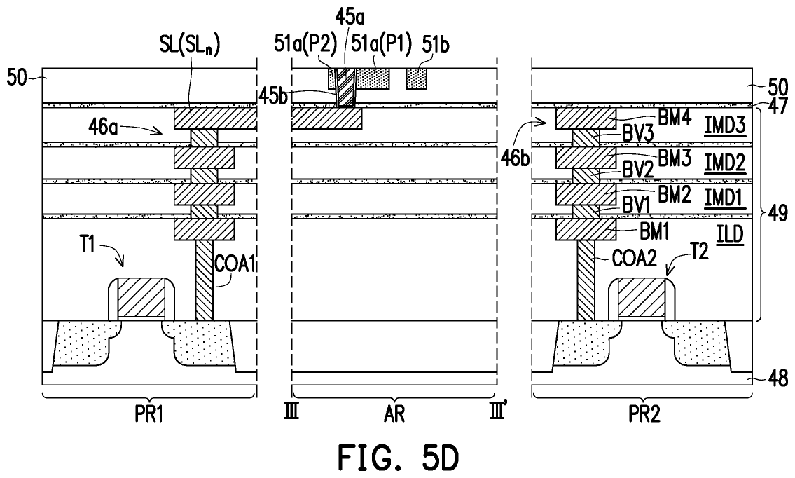

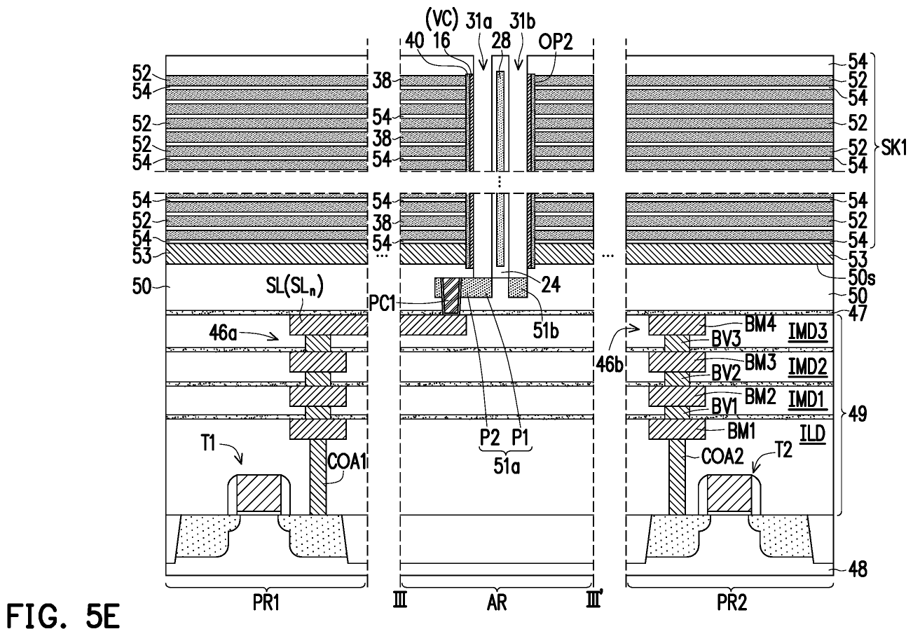

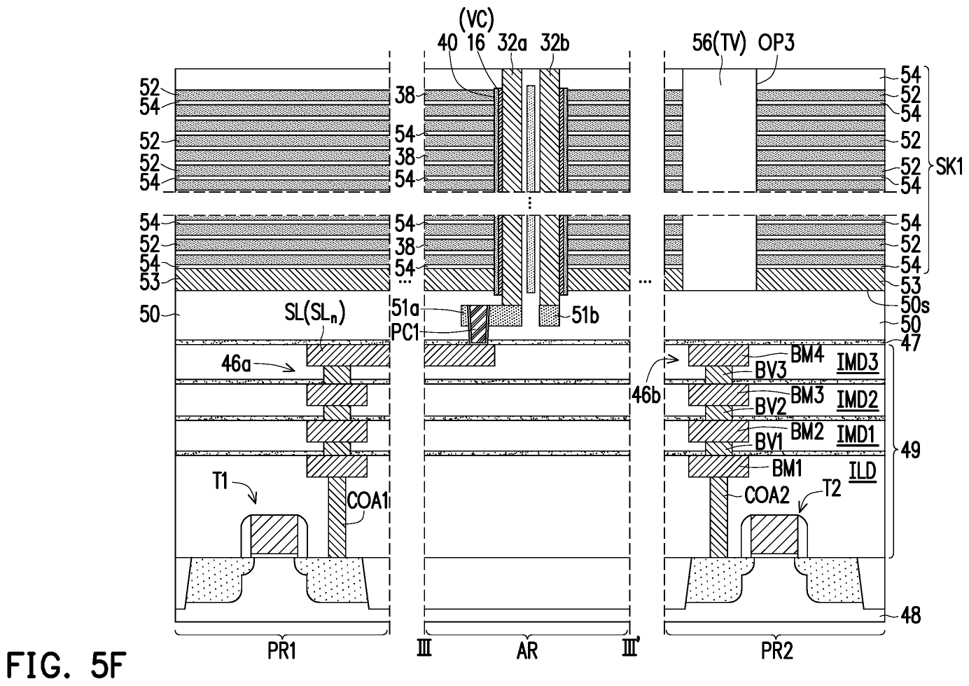

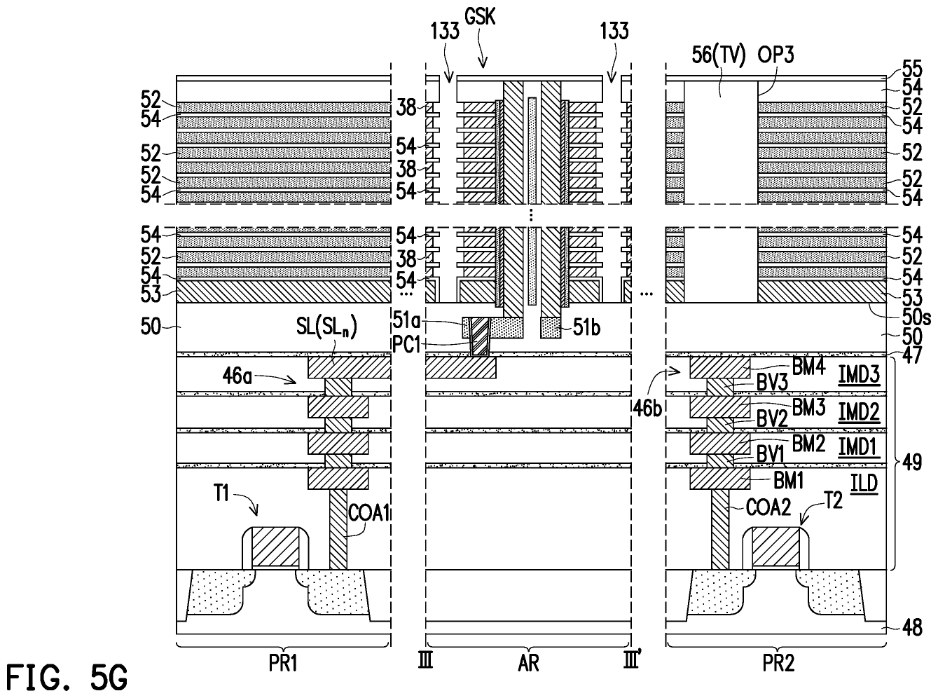

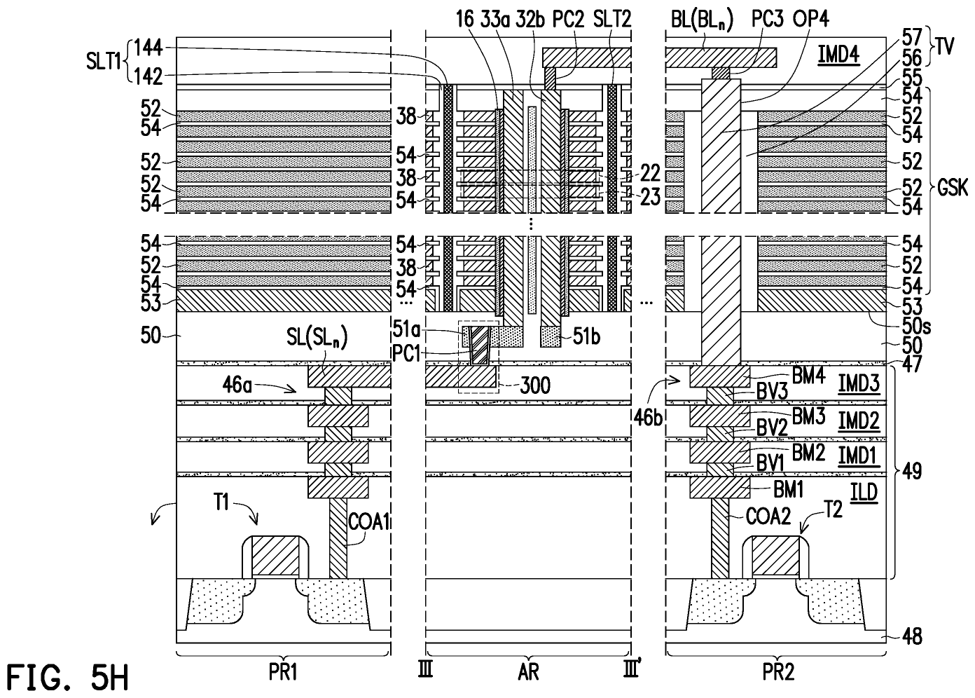

FIG. 5A to FIG. 5H are cross-sectional views of a method for manufacturing a memory device according to an embodiment of the present disclosure.

Referring to FIG. 5A, a substrate 48 is provided. The substrate 48 includes an array region AR and peripheral regions SR1 and SR2. The substrate 48 includes a semiconductor substrate, such as a silicon substrate. The substrate 48 may include devices, such as active devices (e.g., PMOS, NMOS, CMOS, JFET, BJT, diodes, and so on) or passive devices. An interconnect structure 49 is formed on the substrate 48. The interconnect structure 49 may include components, such as an intra-layer dielectric layer ILD, contacts plugs COA1 and COA2, multiple metal layers (or known as conductive lines) BM1, BM2, BM3 and BM4, interlayer dielectric layers IMD1, IMD2, and IMD3, and vias BV1, BV2, and BV3. A stop layer 47 may be included between the intra-layer dielectric layer ILD and the interlayer dielectric layers IMD1, IMD2, and IMD3. A material of each of the intra-layer dielectric layer ILD and the interlayer dielectric layers IMD1, IMD2, and IMD3 may include silicon oxide. A material of the stop layer 47 may include silicon nitride. In an embodiment of the present disclosure, while the metal layer (also known as the conductive line) BM4 is formed, a source line SL (SLₙ) is formed as well. Next, a dielectric layer 50 is formed on the interconnect structure 49. A material of the dielectric layer 50 may include silicon oxide.

Next, referring to FIG. 5B, stop pads 51a and 51b are formed in the dielectric layer 50. A method of forming the stop pads 51a and 51b, for instance, is to form multiple openings OPa and OPb in the dielectric layer 50. Then, a stop material is formed on the dielectric layer 50 and in the openings OPa and OPb. Afterwards, a planarization process is performed, such as a chemical mechanical planarization process, to remove excess stop material on the dielectric layer 50, and the stop material in the openings OPa and OPb serves as the stop pads 51a and 51b. A stop layer includes a conductive material, such as doped polysilicon.

Referring to FIG. 5C, photolithography and etching processes are performed to form an opening OP1. The opening OP1 extends through the second portion P2 of the stop pad 51a, the dielectric layer 50, and the stop layer 47 and exposes the top surface of the source line SL.

Referring to FIG. 5D, a barrier layer 45b and a metal layer 45a are formed in the opening OP1. A method of forming the barrier layer 45b and the metal layer 45a is described as follows. A barrier material and a metal material are formed on the dielectric layer 50 and in the opening OP1. Afterwards, a planarization process is performed, such as a chemical mechanical planarization process, to remove the excess barrier material and the excess metal material on the dielectric layer 50, and the barrier material and the metal material in the opening OP 1 serve as the barrier layer 45b and the metal layer 45a. In some embodiments, top surfaces of the barrier layer 45b, the metal layer 45a, and the stop pads 51a, 51b are coplanar.

Referring to FIG. 5E, a conductive layer 53 is blanketly formed on the dielectric layer 50. The conductive layer includes a P-type doping layer. The conductive layer 53 may be also called a dummy gate, which may be used to close a leakage path. A stacked structure SK1 is formed on the conductive layer 53, and the stacked structure SK1 is patterned to form a staircase structure in the staircase region (not shown). In this embodiment, the stacked structure SK1 includes insulating layers 54 and intermediate layers 52 that are alternately stacked on the conductive layer 53 sequentially. In other embodiments, the stacked structure SK1 may be composed by the intermediate layers 52 and the insulating layers 54 that are sequentially alternately stacked on the conductive layer 53. In addition, in this embodiment, the uppermost layer of the stacked structure SK1 is the insulating layer 54. A material of the insulating layers 54 may include silicon oxide. A material of the intermediate layers 52 may include silicon nitride. The intermediate layers 52 may serve as sacrificial layers, which are partially removed in the subsequent processes. After that, photolithography and etching processes and a trimming process are performed to form a staircase structure SC.

A dielectric layer (not shown) is formed above the substrate 48 to cover the staircase structure SC. A material of the dielectric layer may include silicon oxide. A method of forming the dielectric layer may include forming a dielectric material to cover the staircase structure SC. Afterwards, a planarization process is performed by carrying out a chemical mechanical polishing process, for instance.

Referring to FIG. 5E, after that, multiple channel pillar structures VC are formed in the stacked structure SK1. First, multiple openings OP2 are formed in the stacked structure SK1. The openings OP2 expose the conductive layer 53 or the dielectric layer 50. The etching process may include a dry etching process, a wet etching process, or a combination thereof. The dry etching process may include a plasma etching process. In this embodiment, from the top view, the openings OP2 have a circular shape, but the present disclosure is not limited thereto. In other embodiments, the openings OP2 may have other shapes, such as a polygon shape (not shown). Next, in some embodiments, a portion of the charge storage structure 40 and the channel pillar 16 are formed in the openings OP2. The portion of the charge storage structure 40 includes a tunneling layer 14 and multiple charge storage layers 12, as shown in FIG. 1C. The tunneling layer 14 is made of silicon oxide, for instance. The charge storage layers 12 are made of silicon nitride, for instance.

Referring to FIG. 1D and FIG. 1E, the charge storage structure 40 and the channel pillar 16 may extend through the stacked structure SK1 but do not extend through the conductive layer 53, but the present disclosure is not limited thereto. The channel pillar 16 may be annular from a top view, and may be continuous in its extending direction (e.g., in a direction perpendicular to the surface of the substrate 48). That is, the channel pillar 16 is integral in its extending direction and is not divided into multiple disconnected parts. In some embodiments, the channel pillar 16 may have a circular shape from a top view, but the present disclosure is not limited thereto. In other embodiments, the channel pillar 16 may also have other shapes (such as a polygonal shape) from a top view.

Referring to FIG. 1D and FIG. 1E, an insulating filling material is formed on the stacked structure SK1 and fills the openings OP2. The insulating filling material may include low-temperature silicon oxide. The insulating filling material filling the openings OP2 forms an insulating filling layer 24, and a circular void is left at the center of the insulating filling layer 24. Then, an anisotropic etching process is performed to enlarge the circular void to form a hole 109. An insulating material is formed on the insulating fill layer 24 and filled in the hole 109. Then, an anisotropic etching process is performed to remove a part of the insulating material to form an insulating pillar 28 in the hole 109. A material of the insulating pillar 28 is different from a material of the insulating filling layer 24. The material of the insulating pillar 28 may include silicon nitride.

Referring to FIG. 5E, a patterning process (e.g., photolithography and etching processes) is performed to form holes 31a and 31b in the insulating filling layer 24. Next, the stop pads 51a and 51b may serve as the etching stop layer to continue the etching process until a first portion of the stop pad 51a and the stop pad 51b are exposed. Therefore, the formed holes 31a and 31b extend from the stacked structure SK1 to the exposed first portion P1 of the stop pad 51a and the exposed stop pad 51b. The profiles of the patterns of the holes 31a and 31b defined in the patterning process may be tangent to the profile of the insulating pillar 28, and the profiles of the patterns of the holes 31a and 31b defined in the patterning process may also exceed the profile of the insulating pillar 28 (not shown).

Referring to FIG. 5F, conductive pillars 32a and 32b are formed in the holes 31a and 31b. The conductive pillars 32a and 32b may respectively serve as source and drain pillars and are electrically connected to the channel pillar 16, respectively. The conductive pillars 32a and 32b may be formed by forming a conductive layer on the insulating filling layer 24 and in the holes 31a and 31b, and followed by an etching back. The conductive pillars 32a and 32b may include doped polysilicon.

Referring to FIG. 5F, photolithography and etching processes are performed to form multiple openings OP3 in the stacked structure SK1 in a peripheral region PR2. After that, an insulating material fills the openings OP3 to form an insulating layer 56 of a through via TV. The insulating material is, for example, silicon oxide.

Referring to FIG. 5G, a dielectric layer 55 is formed on the stacked structure SK1. The dielectric layer 55 includes silicon oxide, silicon nitride, or a combination thereof, and the dielectric layer 55 may have a single-layered or a multi-layered structure. Next, the dielectric layer 55 and the stacked structure SKI are patterned to form multiple separation trenches 133. During the etching process, the dielectric layer 50 or the conductive layer 53 may serve as an etching stop layer, so that the separation trenches 133 expose the dielectric layer 50 or the conductive layer 53. The etching process may include a dry etching process, such as a plasma etching process.

Referring to FIG. 5G, a replacement process is performed to the intermediate layers 52. First, an etching process such as a wet etching process is performed to remove a portion of the intermediate layers 52 to form multiple horizontal openings (not shown). Multiple blocking layers 36 and multiple conductive layers 38 are then respectively formed in the horizontal openings, as shown in FIG. 1C. The blocking layers 36 are the other portion of the charge storage structure 40 and may include a material having a high dielectric constant greater than or equal to 7, such as aluminum oxide (Al₂O₃), hafnium oxide (HfO₂), lanthanum oxide (La₂O₅), transition metal oxide, lanthanide oxide, or a combination thereof. The conductive layers 38 may include tungsten. In some embodiments, multiple barrier layers (not shown) are also formed prior to the formation of the conductive layers 38. A material of the barrier layers may include titanium (Ti), titanium nitride (TiN), tantalum (Ta), tantalum nitride (TaN), or a combination thereof.

Referring to FIG. 1D, a method of forming the blocking layers 36, the barrier layers, and the conductive layers 38 includes sequentially forming a blocking material, a barrier material, and a conductive material in the separation trenches 133 and the horizontal openings. Then, an etching back process is performed to remove the blocking material, the barrier material, and the conductive material in the separation trenches 133. The tunneling layer 14, the charge storage layer 12, and the blocking layer 36 are collectively referred to as the charge storage structure 40. The stacked structure GSK is thus formed. The stacked structure GSK is located on the substrate 48, and the stacked structure GSK in the memory array region AR includes multiple conductive layers 38 and multiple insulating layers 54 alternately stacked, while the stacked structure GSK in the peripheral regions PR1 and PR2 includes multiple intermediate layers 52 and multiple insulating layers 54 alternately stacked.

Referring to FIG. 5H, separation structures SLT1 and SLT2 are then formed in the separation trenches 133. Each of the separation structures SLT1 and SLT2 may have a single-layer or multi-layer structure. In some embodiments, a method of forming the separation structure SLT1 and SLT2 is described as follows. An insulating liner material and a conductive material fill the stacked structure GSK and the separation trenches 133. The insulating liner material may include silicon oxide, for instance. The conductive material may include polysilicon, for instance. Then, the excess insulating liner material and conductive material on the stacked structure GSK are removed through an etching back process or a planarization process, so as to form a liner layer 142 and a conductive layer 144. The liner layer 142 and the conductive layer 144 form the separation structures SLT1 and SLT2. In some embodiments, the separation structures SLT1 and SLT2 may also be completely filled with an insulating material without any conductive material. In some other embodiments, the separation structure s SLT1 and SLT2 may be a liner layer covering an air gap without any conductive material.

Referring to FIG. 5H, conductive vias 57 are formed in the insulating layer 56 of the through vias TV1. The conductive vias 57 are located in the insulating layer 56 and extend through the insulating layer 56 and the dielectric layer 50, land on and are electrically connected to the topmost metal layer BM4 of the interconnect structure 49. A method for forming the conductive vias 57 includes performing photolithography and etching processes to form multiple openings OP4 in the insulating layer 56. The openings OP4 penetrate the insulating layer 56 and the dielectric layer 50 and expose the topmost metal layer BM4 of the interconnect structure 49. Next, a conductive material is formed on the substrate 48, and the conductive material fills the openings OP4. The conductive material may include tungsten or polysilicon, for instance. Afterwards, a planarization process such as a chemical mechanical polishing process is performed to remove the conductive material outside the openings OP4.

Referring to FIG. 5H, a dielectric layer IMD4 is formed on the stacked structure GSK, and conductive plugs PC2 and PC3 and bit lines BL (BLₙ) are formed in the dielectric layer IMD4. The conductive plugs PC2 and PC3 and the bit lines BL may be formed by any known method.

In view of the above, in one or more embodiments of the present disclosure, the source lines are formed below the stacked structure, while the bit lines are formed above the stacked structure. Therefore, the density of the conductive lines (the bit lines) above the stacked structure is reduced, and the width of and the distance between the conductive lines (the bit lines) are increased. As a result, the resistance values of the conductive lines (the bit lines) are reduced, and the difficulty of the manufacturing process is lowered. In addition, the bit lines may be electrically connected to the source pillars through the stop pads located below the source pillars and the conductive plugs penetrating the stop pads. Therefore, the memory device provided in one or more embodiments of the present disclosure may be integrated with the existing manufacturing processes.

What is claimed is:

1. A memory device, comprising:
a substrate;
an interconnect, located above the substrate;
a first stop pad and a second stop pad, located above the interconnect;
a stacked structure, located above the first stop pad and the second stop pad;
a channel pillar, extending through the stacked structure;
a charge storage structure, located between the channel pillar and the stacked structure;
a first conductive pillar and a second conductive pillar, located in the channel pillar and coupled to the channel pillar, wherein the first conductive pillar lands on the first stop pad, and the second conductive pillar lands on the second stop pad; and
a first conductive plug, located between the interconnect and the first stop pad, wherein the first conductive pillar is electrically connected to a first device on the substrate through the first conductive plug, the first stop pad, and the interconnect.

2. The memory device according to claim 1, wherein the first conductive plug extends through a bottom surface of the first stop pad from a top surface of the first stop pad and is coupled to a bit line, and the bit line is electrically connected to the first device through the interconnect located below the bit line.

3. The memory device according to claim 1, further comprising: a stop layer located on the interconnect, wherein the first conductive plug further extends through the stop layer and is coupled to a source line.

4. The memory device according to claim 1, wherein an area occupied by the first stop pad is larger than an area occupied by the second stop pad.

5. The memory device according to claim 1, wherein the first stop pad comprises:
a first portion, partially located in the channel pillar, wherein a top surface of the first portion is connected to the first conductive pillar; and
a second portion, located outside the channel pillar, wherein the first conductive plug extends through a top surface of the second portion to a bottom surface of the second portion.

6. The memory device according to claim 5, wherein an area occupied by the second portion of the first stop pad is larger than an area occupied by the first portion of the first stop pad.

7. The memory device according to claim 6, further comprising a separation wall extending through the stacked structure, wherein the second portion of the first stop pad is located between the channel pillar and the separation wall.

8. The memory device according to claim 6, wherein the first conductive plug is located between the separation wall and the first conductive pillar.

9. The memory device according to claim 1, further comprising:
a through via, penetrating the stacked structure and connected to the interconnect;
a conductive line, located above the stacked structure;
a second conductive plug, connecting the conductive line and the second conductive pillar; and
a third conductive plug, connecting the conductive line and the through via, wherein the second conductive pillar is electrically connected to a second device on the substrate through the second conductive plug, the conductive line, the third conductive plug, the through via, and the interconnect.

10. The memory device according to claim 1, wherein a top surface of the first conductive pillar is completely covered by a dielectric layer, and no conductive plug lands on the top surface of the first conductive pillar.

11. A memory device, comprising:
a substrate;
an interconnect, located above the substrate;
a plurality of first stop pads and a plurality of second stop pads, located above the interconnect;
a stacked structure, located above the first stop pads and the second stop pads;
a plurality of channel pillars, extending through the stacked structure and arranged in two adjacent rows;
a plurality of pairs of conductive pillars, wherein each of the pairs of the conductive pillars is disposed in one of the channel pillars, a first conductive pillar of the each of the pairs of the conductive pillars lands on one of the first stop pads, and a second conductive pillar of the each of the pairs of the conductive pillars lands on one of the second stop pads; and
a plurality of first conductive plugs, located between the interconnect and the first stop pads, wherein each of the first conductive pillars is electrically connected to a first device on the substrate through a corresponding first conductive plug of the first conductive plugs, a corresponding first stop pad of the first stop pads, and the interconnect,
wherein the second conductive pillars are adjacent to each other and are located between the first conductive pillars.

12. The memory device according to claim 11, wherein in a top view, the second stop pads are arranged between the first stop pads.

13. The memory device according to claim 11, wherein in the channel pillars arranged in the two adjacent rows, each of the pairs of the conductive pillars in a first row of the two adjacent rows is arranged along a first direction, each of the pairs of the conductive pillars in a second row of the two adjacent rows is arranged along a second direction, and the first direction is different from the second direction.

14. The memory device according to claim 11, wherein the first stop pads comprise:
a plurality of first portions, located in the channel pillars, wherein top surfaces of the first portions are connected to the first conductive pillars; and
a plurality of second portions, located outside the channel pillars, wherein the first conductive plugs extend through top surfaces of the second portions to bottom surfaces of the second portions.

15. The memory device according to claim 14, wherein an area occupied by the second portions is larger than an area occupied by the first portions.

16. The memory device according to claim 14, wherein the first portions are arranged in two rows, and the second portions are arranged in two rows.

17. The memory device according to claim 16, wherein the first conductive plugs are arranged in two rows, and in a top view, the channel pillars in the two adjacent rows are located between the two rows of the first conductive plugs.

18. The memory device according to claim 11, further comprising:
a plurality of separation walls, extending through the stacked structure, wherein the second portions are located between the channel pillars and the separation walls.

19. The memory device according to claim 11, further comprising:
a plurality of through vias, penetrating the stacked structure and connected to the interconnect;
a plurality of conductive lines, located above the stacked structure;
a plurality of second conductive plugs, connecting the conductive lines and the second conductive pillars;
a plurality of third conductive plugs, connecting the conductive lines and the through vias, wherein one of the second conductive pillars is electrically connected to a second device on the substrate through a corresponding second conductive plug of the second conductive plugs, a corresponding conductive line of the conductive lines, a corresponding third conductive plug of the third conductive plugs, a corresponding through via of the through vias, and the interconnect.

20. The memory device according to claim 19, wherein the conductive lines are separated by a dielectric layer, top surfaces of the first conductive pillars are completely covered by the dielectric layer, and no conductive plug lands on the top surfaces of the first conductive pillars.
